(19) United States
(12) Patent Application Publication
(10) Pub. No.: US 2014/0095089 A1
(43) Pub. Date: Apr. 3, 2014

(54) SYSTEM AND METHOD FOR ESTIMATED BATTERY STATE OF CHARGE

(71) Applicants: Zhijian James Wu, Rochester Hills, MI (US); Brian P. Gebby, Macomb Township, MI (US)

(72) Inventors: Zhijian James Wu, Rochester Hills, MI (US); Brian P. Gebby, Macomb Township, MI (US)

(21) Appl. No.: 13/633,470

(22) Filed: Oct. 2, 2012

(51) Int. Cl. G01R 31/36; G06F 19/00

(52) U.S. Cl. 702/63

(57) ABSTRACT

A method for diagnosing an estimated battery state of charge is provided. The method includes estimating a first state of charge of a battery at a first time with a state-of-charge sensor, estimating a second state of charge of the battery at the first time, calculating a difference between the first state of charge and the second state of charge, and comparing the difference between the first state of charge and the second state of charge to a predetermined value to determine whether the battery sensor is within operating parameters. A system for estimating battery state of charge is further provided. The system includes a state-of-charge sensor configured to estimate a first state of charge of a battery at a first time, and a processor connected to the battery sensor and configured to estimate a second state of charge of the battery at the first time, and compare a difference between the first state of charge to the second state of charge to a predetermined value to determine whether the battery sensor is within operating parameters.

### FIELD

The present disclosure relates to diagnosis of an estimated state of charge of a battery. More specifically, the present disclosure relates to the on-board diagnosis of an intelligent battery sensor used to estimate the state of charge of a battery.

### BACKGROUND

Many modern vehicle types, including regular vehicles, auto-start-stop vehicles, hybrid vehicles, and battery electric vehicles, utilize a battery to power electronic systems or, in some cases, provide locomotion. Because these vehicles rely so heavily on the battery for operation, they typically employ a system or device for monitoring the battery. Commonly, battery monitoring systems are separate dedicated systems, but a battery monitoring system can also be integrated into a battery management system, a vehicle controller unit, or an engine control unit (“ECU”). When used in regular vehicles or auto-start-stop vehicles, dedicated battery monitoring systems typically include a plurality of sensors and a processor designed to monitor many different battery variables. This dedicated device is commonly referred to as an intelligent battery sensor (“IBS”). The IBS can monitory battery run time, typically by estimating the battery state of charge, in addition to providing battery voltage, battery current and battery temperature estimations.

The IBS may estimate battery state of charge based upon measurable variables. Generally, two types of systems are used to estimate battery state of charge. The first type utilizes a battery voltage measurement to estimate the battery state of charge. The second type of system utilizes a battery current measurement to estimate the battery state of charge. Both systems use complicated estimation techniques, such as Kalman filtering methods, in combination with measured variables to calculate the battery state of charge.

In auto-start-stop, hybrid vehicles and battery electric vehicles, battery state of charge is a desirable parameter for motor control and vehicle operation, and therefore is desirable to be diagnosed on-board. In other vehicles, it is desirable to diagnose the battery state of charge on-board in the ECU because battery state of charge is used as an input to emissions control algorithms. While methods used by battery monitoring systems to estimate battery state of charge may be known, there remains room for improvement in the art.

### SUMMARY

In one form, the present disclosure provides a method for diagnosis of an estimated battery state of charge from a state-of-charge sensor. The method includes estimating a first state of charge of a battery at a first time with a state-of-charge sensor, estimating a second state of charge of the battery at the first time, calculating a difference between the first state of charge and the second state of charge, and comparing the difference between the first state of charge and the second state of charge to a predetermined value to determine whether the state-of-charge sensor is within operating parameters.

In another form, the present disclosure provides a system for diagnosis of an estimated battery state of charge from a state-of-charge sensor. The system includes a state-of-charge sensor configured to estimate a first state of charge of a battery at a first time, and a processor connected to the state-of-charge sensor and configured to estimate a second state of charge of the battery at the first time, and compare a difference between the first state of charge to the second state of charge to a predetermined value.

Additionally, a system in accordance with the disclosed principles can diagnose whether a state-of-charge sensor is overestimating battery state of charge at low battery voltages or underestimating battery state of charge at high battery voltages.

The present disclosure provides an on-board diagnostic for a state-of-charge sensor without the need for additional circuitry. Consequently, the present disclosure reduces the cost and complexity of performing on-board diagnostics.

Further areas of applicability of the present disclosure will become apparent from the detailed description, drawings and claims provided hereinafter. It should be understood that the detailed description, including disclosed embodiments and drawings, are merely exemplary in nature intended for purposes of illustration only and are not intended to limit the scope of the invention, its application or use. Thus, variations that do not depart from the gist of the invention are intended to be within the scope of the invention.

### BRIEF DESCRIPTION OF THE DRAWINGS

FIG. 1 is a block diagram of a system for diagnosis of an estimated battery state of charge from a state-of-charge sensor in accordance with the disclosed principles;

FIG. 2 is a flow chart for a method for diagnosis of an estimated battery state of charge from a state-of-charge sensor when the battery is charging;

FIG. 3 is a flow chart for a method for diagnosis of an estimated battery state of charge from a state-of-charge sensor when the battery is discharging;

FIG. 4 is a flow chart for a method of determining whether a state-of-charge sensor is overestimating battery state of charge when the estimated battery state of charge is low; and

FIG. 5 is a flow chart for a method of determining whether a state-of-charge sensor is underestimating battery state of charge when the estimated battery state of charge is high.

### DETAILED DESCRIPTION

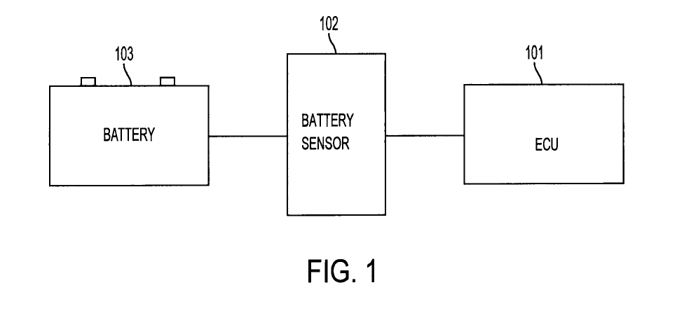

Referring now to the drawings, FIG. 1 is a block diagram showing a system for diagnosis of an estimated battery state of charge in accordance with the disclosed principles. The exemplary system includes of an engine control unit (“ECU”) 101, a battery sensor 102, and a battery 103. The ECU 101 is a type of electronic control unit that is responsible for optimizing the performance of a number of systems in an automobile by reading values from a multitude of sensors within the engine bay, interpreting the data, and adjusting the systems accordingly. One of the sensors connected to the ECU 101 is the battery sensor 102. The battery sensor 102 is connected to the battery 103, and is configured to measure battery voltage or battery current. Based upon these measurements, the battery sensor 102 estimates a battery state of charge.

The exemplary system described above with reference to FIG. 1 is not intended to limit the invention to a battery sensor 102 and an ECU 101. It should be appreciated that diagnosis of an estimated state of charge of a battery in accordance with the disclosed principles can be accomplished with any state-of-charge sensor and a processor configured to perform the calculations described herein.

In the exemplary embodiment, the battery sensor 102 is configured to estimate the battery state of charge as a percentage value. The battery sensor 102 provides battery state of charge estimates to the ECU 101 with a one percent resolution, at a 500 ms sampling rate. The battery sensor 102 may use estimation techniques such as Kalman filtering, combined with battery current and voltage measurements, to estimate battery state of charge.

In order to diagnose proper operation of the battery sensor 102, the ECU 101 is also configured to estimate the battery state of charge. Preferably, the ECU 101 estimates the battery state of charge by integrating battery charge or discharge currents; a method known as Coulomb counting.

The algorithm used by the ECU 101 to diagnose operation of the battery sensor 102 compares variations in the ECU estimated state of charge and the battery sensor estimated state of charge for a single time period. What this means is that the ECU 101 compares the ECU 101 estimated state of charge at the end of the time period to the battery sensor estimated state of charge at the end of the time period. The ECU 101 then calculates the difference between these two estimates. The difference is compared to a predetermined threshold value. The predetermined threshold value represents the maximum acceptable deviation between the ECU 101 estimated state of charge and the battery sensor estimated state of charge. The predetermined threshold value itself is largely dependent upon the characteristics of the battery 103, and is therefore individually determined based thereon.

The time period used by the ECU 101 when making the comparison described above can be determined in a number of ways. For example, in the exemplary embodiment, the time period used by the ECU 101 in comparing the ECU estimated state of charge to the battery sensor estimated state of charge is determined by the time it takes the battery sensor 102 to register a one percent change in the battery sensor estimated state of charge. Typically, it takes the battery sensor 102 several minutes to register a one percent change in the estimated state of charge. It should be appreciated that the time period could measured by any percentage change in the battery sensor estimated state of charge. The time period could even be determined independent of the battery sensor 102, so long as it allows time for variations in the battery sensor estimated state of charge to register.

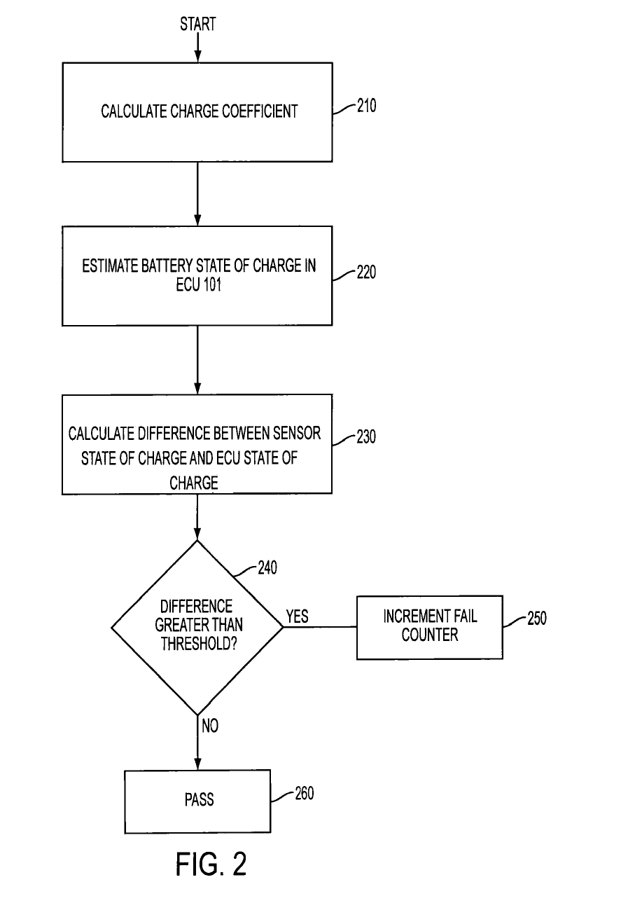

Preferably, the ECU 101 is configured to perform four diagnostic tests. The methods for performing these diagnostic tests will be discussed in detail below, with reference to FIGS. 2-5.

FIG. 2 is a flow chart for a method of diagnosing proper operation of a battery sensor when the battery 103 is charging. The first step in performing this diagnostic is calculating a charge coefficient (step 210). The charge coefficient can be calculated, for example, using the following formula:

Charge Coefficient Bₑ=100K_{c}Δt/C

where C is the battery capacity in Ampere-hours, Δt is the sampling time, and K_{c} is a charging correction factor depending on, among other things, battery temperature, age and current. Typically the correction factor ranges from 0.9 to 1.1. It is possible to adaptively determine the charge coefficient B_{c} in real time based on other variables more accurate estimation of state of charge.

The ECU 101 then uses the charge coefficient to estimate the battery state of charge (ΔSOC) for a particular time period (step 220) with the following formula:

$$Δ SOC ( \% ) = {B}_{c} {\sum }_{i = 1}^{n} {I}_{i}$$

Where Iᵢ is battery current in Amperes at sampling time i, and n is the total number of samples in the particular time period.

Next, the ECU 101 calculates the difference between the ECU 101 estimated state of charge at the end of the time period and the battery sensor estimated state of charge at the end of the time period (step 230). After calculating the difference between the two state of charge estimates, the ECU 101 compares the difference to a predetermined charging threshold value (240). If the difference is less than the charge value, the battery sensor 102 has passed the diagnostic test. If the difference is greater than the charging threshold value, the battery sensor increments a failure counter (250).

The charging threshold value is based on the ECU estimated state of charge for a particular time period as well as the battery sensor's degree of accuracy. For example, if the ECU estimates the battery state of charge every time the battery sensor estimated state of charge changes by 1 percent, the threshold value may be set to 0.2 percent. That is, if the difference between the two state of charge estimates is larger than 0.2 percent, the test is counted as a failure. The threshold value is chosen to ensure not only a high probability of fault detection when the battery sensor fails to increment properly, but also to maintain a low false detection probability.

In one aspect, the ECU 101 will transmit a malfunction signal if the failure counter exceeds an acceptable number. For example, in the exemplary system, the ECU 101 will transmit a malfunction signal if the failure counter exceeds 3. Once the malfunction signal is sent to an on-board diagnostic task management system, the ECU 101 will notify vehicle's operator of the malfunction, for example, by displaying a malfunction light.

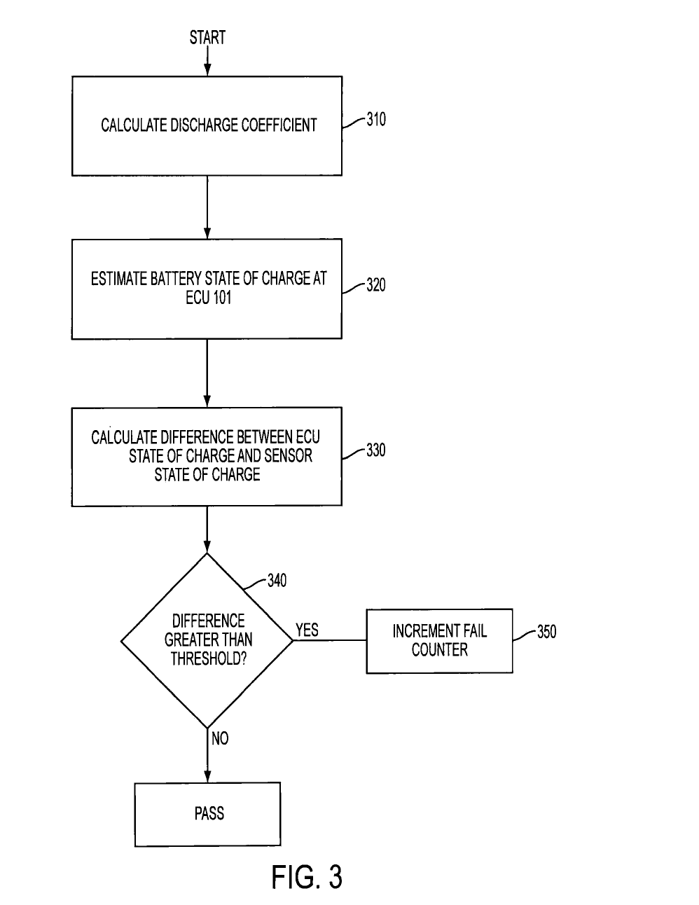

FIG. 3 is a flow chart for a method of diagnosing proper operation of a battery sensor when the battery is discharging. The first step in performing this diagnostic is calculating a discharge coefficient (step 310). The discharge coefficient can be calculated, for example, using the following formula:

Discharge Coefficient B_{d}=100K_{d}Δt/C

where C is the battery capacity in Ampere-hours (Ah), Δt is the sampling time, and K_{d} is a discharging correction factor depending on, among other things, battery temperature, age, and current. Typically the discharging correction factor ranges from 0.9 to 1.1. It is possible to adaptively determine the discharging correction factor in real time based on other variables.

The ECU 101 then uses the discharge coefficient to estimate the battery state of charge for a particular time period (step 320) using the following formula:

$$Δ SOC ( \% ) = {B}_{d} {\sum }_{i = 1}^{n} {I}_{i}$$

where Iᵢ is battery current in Amperes at sampling time i, and n is the total sample numbers in the particular time period.

The ECU 101 then calculates the difference between the ECU 101 estimated state of charge and the battery sensor estimated state of charge at the end of the time period (step 330). Next, the ECU 101 compares the difference between the two state of charge estimates to a predetermined threshold value (340). If the difference is less than the threshold value, the battery sensor 102 has passed the diagnostic test. If the difference is greater than the threshold value, the battery sensor increments a failure counter (350).

The discharging threshold value is calculated based on the ECU estimated state of charge for a particular time period as well as the battery sensor's degree of accuracy. For example, if the ECU estimates the battery state of charge every time the battery sensor estimated state of charge changes by 1 percent, the threshold value may be set to 0.2 percent. That is, if the difference between the two state of charge estimates is larger than 0.2 percent, the test is counted as a failure. The threshold value is chosen to ensure not only a high probability of fault detection when the battery sensor fails to increment properly, but also to maintain a low false detection probability.

In one aspect, the ECU 101 will transmit a malfunction signal if the failure counter exceeds an acceptable number. For example, in the exemplary system, the ECU 101 will transmit a malfunction signal if the failure counter exceeds 3. Once the malfunction signal is sent to an on-board diagnostic task management system, the ECU 101 will notify vehicle's operator of the malfunction, for example, by displaying a malfunction light.

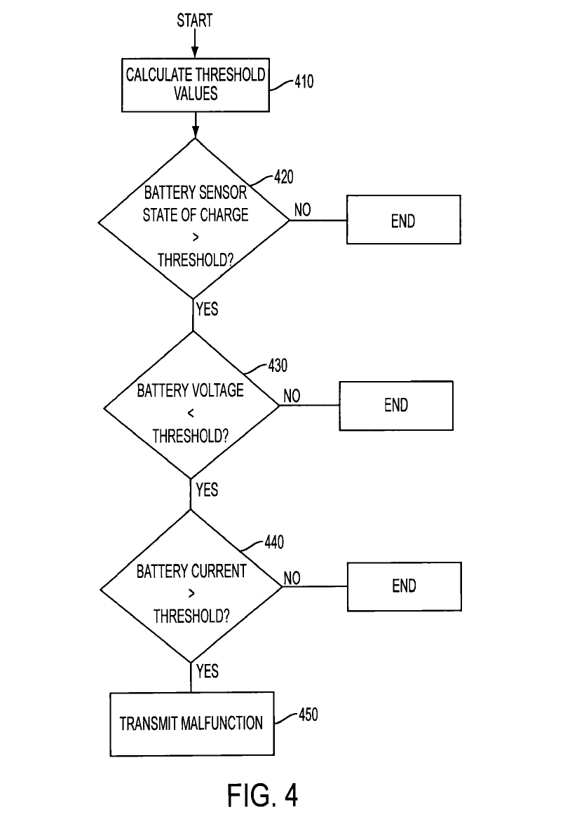

FIG. 4 is a flow chart for a method of determining whether a battery sensor is overestimating battery state of charge when the actual battery state of charge is low. This diagnostic ensures that the battery sensor 102 is not overestimating the amount of battery charge when the battery 103 has already discharged significantly. In order to perform this diagnostic, the ECU 101 first calculates three threshold values (step 410) for a battery voltage, a battery current, and a battery sensor estimated state of charge. It is assumed that the battery current is positive when the battery is charging and negative when the battery is discharging. These threshold values will be compared to battery measurements in subsequent steps. For example, in the preferred embodiment, the battery voltage threshold is 10V, the battery current threshold is 5 A, and the battery sensor estimated state of charge is 80%.

The ECU 101 first compares the battery sensor estimated state of charge to its corresponding threshold value (step 420). If the battery sensor estimated state of charge is not greater than or equal to its corresponding threshold value, the ECU will end the diagnostic. If the battery sensor estimated state of charge is greater than its corresponding threshold value, the ECU will then compare a battery voltage measurement to its corresponding threshold value (step 430). If the battery voltage is greater than or equal to its corresponding threshold value, the ECU 101 will end the diagnostic because it cannot determine whether the battery sensor 102 has overestimated the state of charge at this condition. If the battery voltage is less than its corresponding threshold value, the ECU 101 will move on to step 440.

In step 440, the ECU 101 compares a battery current measurement to its corresponding threshold value. If the battery current is not greater than or equal to its corresponding threshold value, the ECU 101 will end the diagnostic because it cannot determine whether the battery sensor 102 has overestimated the state of charge at this condition. However, if the battery current is larger than its corresponding threshold value, the battery sensor 102 has failed the diagnostic and is likely overestimating the battery 103 state of charge. The ECU examines the battery current to prevent a false decision at a large discharge condition, such as in a cranking period where the voltage is low but the state of charge is high. Preferably, the ECU 101 will transmit a malfunction signal if the battery sensor 102 fails all parts of this diagnostic test (step 450).

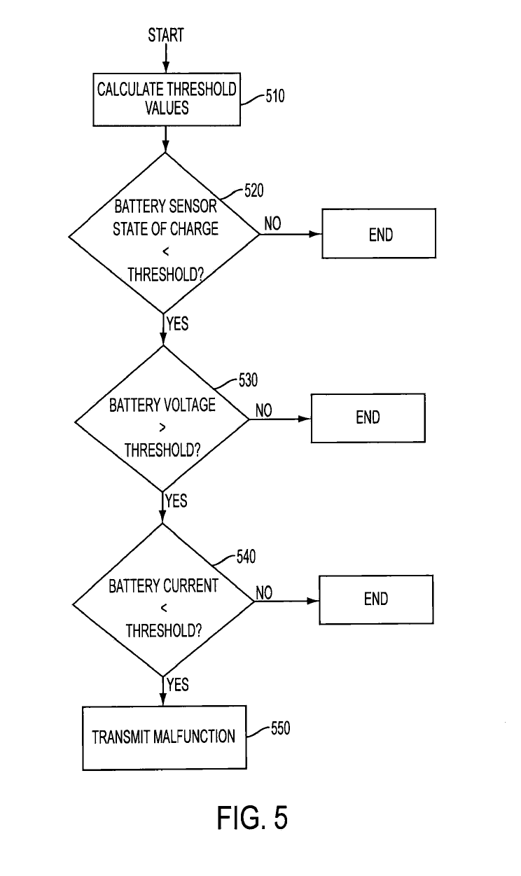

FIG. 5 is a flow chart for a method of determining whether a battery sensor is underestimating battery state of charge when the actual battery state of charge is high. Just like the method described with reference to FIG. 4 above, the first step requires calculation of threshold values (step 510) for battery voltage, battery current, and battery sensor estimated state of charge. For example, in the preferred embodiment, the battery voltage threshold is 14V, the battery current threshold is −5 A, and the battery sensor estimated state of charge threshold is 40%. These threshold values will be compared to a corresponding measurement in subsequent steps.

After calculating the threshold values, the ECU 101 first compares the battery sensor estimated state of charge to its corresponding threshold value (step 520). If the battery sensor estimated state of charge is greater than or equal to its corresponding threshold value, the ECU will end the diagnostic. If the battery sensor estimated state of charge is less than its corresponding threshold value, the ECU will then compare a battery voltage measurement to its corresponding threshold value (step 530). The battery voltage measurement is an instantaneous battery voltage. If the battery voltage is less than or equal to its corresponding threshold value, the ECU 101 will end the diagnostic because it cannot determine whether the battery sensor 102 has underestimated the state of charge at this condition. If the battery voltage is greater than its corresponding threshold value, the ECU 101 will move on to step 540.

In step 540, the ECU 101 compares a battery current measurement to its corresponding threshold value. If the battery current is greater than or equal to its corresponding threshold value, the ECU will end the diagnostic because it cannot determine whether the battery sensor 102 has underestimated the state of charge at this condition. However, if the battery current is less than its corresponding threshold value, the battery sensor 102 has failed the diagnostic and is likely overestimating the battery state of charge. The ECU examines the battery current to prevent a false decision at a large charge condition where the voltage is high but the state of charge is low. Preferably, the ECU 101 will transmit a malfunction signal if the battery sensor 102 fails the diagnostic test (step 550).

What is claimed is:

1. A method for diagnosing an estimated battery state of charge, the method comprising:
estimating a first state of charge of a battery at a first time with a state-of-charge sensor;
estimating a second state of charge of the battery at the first time;
calculating a difference between the first state of charge and the second state of charge with a processor; and
comparing the difference between the first state of charge and the second state of charge to a predetermined value to determine whether the state-of-charge sensor is within operating parameters with the processor.

2. The method of claim 1, further comprising incrementing a counter when the difference between the first state of charge and the second state of charge is greater than the predetermined value.

3. The method of claim 2, further comprising transmitting a failure signal when the counter is greater than a second predetermined value.

4. The method of claim 1, wherein the state-of-charge sensor is configured to estimate the first state of charge by measuring a voltage and a current of the battery.

5. The method of claim 1, wherein the second state of charge is estimated by integrating a plurality of measurements of a current of the battery over a predetermined period.

6. The method of claim 1, further comprising determining whether a state-of-charge sensor is overestimating the first battery state of charge.

7. The method of claim 1, further comprising determining whether a state-of-charge sensor is underestimating the first battery state of charge.

8. The method of claim 1, wherein the second state of charge is estimated by the processor.

9. A system for diagnosing an estimated battery state of charge comprising:
a state-of-charge sensor configured to estimate a first state of charge of a battery at a first time; and
a processor connected to the state-of-charge sensor and configured to estimate a second state of charge of the battery at the first time, and compare a difference between the first state of charge to the second state of charge to a predetermined value to determine whether the state-of-charge sensor is within operating parameters.

10. The system of claim 9, wherein the battery sensor is configured to estimate the first state of charge by measuring a voltage and a current of the battery.

11. The system of claim 9, wherein the processor is configured to estimate the second state of charge by integrating a plurality of measurements of a current of the battery over a predetermined period.

12. The system of claim 9, wherein the processor is configured to increment a counter when the difference between the first state of charge and the second state of charge is greater than the predetermined value.

13. The system of claim 12 wherein the processor is configured to transmit a failure signal when the counter is greater than a second predetermined value.

14. The method of claim 9, further comprising determining whether a state-of-charge sensor is overestimating the first battery state of charge.

15. The method of claim 9, further comprising determining whether a state-of-charge sensor is underestimating the first battery state of charge.
